(19) United States
(12) Patent Application Publication
(10) Pub. No.: US 2019/0302506 A1
(43) Pub. Date: Oct. 3, 2019

(54) METHOD FOR MANUFACTURING LIQUID CRYSTAL DISPLAY DEVICE, AND LIQUID CRYSTAL DISPLAY DEVICE

(71) Applicant: SHARP KABUSHIKI KAISHA, Osaka (JP)

(72) Inventors: JUN NISHIMURA, Sakai City (JP); YOSHIMASA CHIKAMA, Sakai City (JP); YOSHIHARU HIRATA, Sakai City (JP); HAJIME IMAI, Sakai City (JP); TOHRU DAITOH, Sakai City (JP)

(21) Appl. No.: 16/365,176

(22) Filed: Mar. 26, 2019

Related U.S. Application Data
(60) Provisional application No. 62/649,724, filed on Mar. 29, 2018.

(51) Int. Cl. G02F 1/1339; G02F 1/1368; G02F 1/1335; G03F 7/20

(52) U.S. Cl. CPC G02F 1/13394; G02F 1/1368; G02F 2001/13396; G03F 7/20; G02F 1/133512

(57) ABSTRACT

The present invention provides a method for manufacturing a liquid crystal display device in which a decrease in the aperture ratio is prevented while the load capacity is maintained. The method for manufacturing a liquid crystal display device of the present invention includes a step (A-1) of applying a negative photoresist to a surface of a first substrate including a thin-film transistor element to form a first film, a step (A-2) of exposing the first film in an exposure pattern including a first exposure region and a second exposure region in which an exposure dose is lower than an exposure dose in the first exposure region, and a step (A-3) of developing the first film to form a first spacer in the first exposure region and a second spacer with a height less than a height of the first spacer in the second exposure region.

### CROSS-REFERENCE TO RELATED APPLICATIONS

The present application claims priority under 35 U.S.C. § 119 to U.S. Provisional Application No. 62/649,724 filed on Mar. 29, 2018, the contents of which are incorporated herein by reference in their entirety.

### BACKGROUND OF THE INVENTION

### Field of the Invention

The present invention relates to methods for manufacturing liquid crystal display devices and liquid crystal display devices.

### Description of Related Art

Liquid crystal display devices have a structure in which a liquid crystal layer is disposed between a pair of substrates. In common liquid crystal display devices, spacers are disposed to maintain the space between a pair of substrates (the thickness of a liquid crystal layer) (see, for example, JP 4991754 B, JP 2003-84289 A, JP 2003-186022 A, and JP 2017-167478 A).

### BRIEF SUMMARY OF THE INVENTION

The present inventors studied to find that when a substrate including thin-film transistor elements is used as one of the pair of substrates in a liquid crystal display device, the spacers formed on the surface of the substrate using a negative photoresist (photosensitive resin) each have a tapered shape cross section. However, such spacers each have a wide bottom edge. In order to solve such a problem, the spacers are hidden with a black matrix in a plan view using the other substrate including the black matrix. However, the bottom edges of such spacers are exposed out of the black matrix. This sometimes disturbs the alignment of liquid crystal molecules, which is visually observed.

In order to increase the load capacity of liquid crystal display devices, a technique of providing not only a main spacer that maintains the space between the pair of substrates but also a sub-spacer with a height less than the height of the main spacer is known. The top of the main spacer is constantly in contact with the counter substrate, whereas the top of the sub-spacer is not in contact with the counter substrate when no load is applied to the liquid crystal display device. Such a top of the sub-spacer comes into contact with the counter substrate when the space between the pair of substrates is reduced in the liquid crystal display device under load. The main spacer and the sub-spacer support the pair of substrates together when a load is applied to the liquid crystal display device. Thereby, the load capacity increases. In order to increase the load capacity, the contact area between the top of the sub-spacer and the counter substrate is desired to increase, that is, the area of the top of the sub-spacer is desired to increase.

The present inventors studied such a technique to find that when a sub-spacer having a top with a large area is formed using a negative photoresist on the surface of a substrate including thin-film transistor elements, the area of the bottom of the sub-spacer also increases, and thus the bottom edge of the sub-spacer significantly becomes wide. In order to hide such a wide bottom edge of the sub-spacer with a black matrix, a black matrix with a large width is needed. However, it decreases the aperture ratio.

The present inventors made various studies on the cause of an increase in the width of the bottom edge of a spacer to find the following facts. A substrate including thin-film transistor elements usually contains materials such as a transparent material with high light transmittance and a metal material with high light reflectance. When a negative photoresist is applied to the surface of the substrate including thin-film transistor elements and exposed to light, reflected light or stray light generates from the stage of the exposure apparatus and enters an underlying layer region of the transparent material or reflected light or stray light generates from an underlying layer region of the metal material. Thereby, a larger area of the photoresist than the desired area is exposed to light. As a result, a spacer with a wide bottom edge is formed. In contrast, when a negative photoresist applied to the surface of the substrate including a black matrix is exposed to light, the black matrix with low light reflectance (with high light absorptivity) serving as an underlying layer prevents unnecessary reflected light and stray light. As a result, an increase in the width of the bottom edge of the formed spacer is prevented.

As described above, the formation of spacers on the surface of the substrate including thin-film transistor elements using a negative photoresist has problems in achieving prevention of a decrease in the aperture ratio while the load capacity is maintained. The solution to such problems has not been found so far. For example, JP 4991754 B discloses a method of forming a spacer on the surface of an active matrix substrate using a positive photoresist. It however only discloses the formation of spacers at positions restricted by the pattern of an underlying layer and does not disclose the bottom edge of spacers. JP 2003-84289 A, JP 2003-186022 A, and JP 2017-167478 A also do not disclose an increase in the width of the bottom edge of spacers.

The present invention has been made in view of such a current state of the art and aims to provide a method for manufacturing a liquid crystal display device in which a decrease in the aperture ratio is prevented while the load capacity is maintained, and a liquid crystal display device manufactured by this method.

The present inventors made various studies on the method for manufacturing a liquid crystal display device in which a decrease in the aperture ratio is prevented while the load capacity is maintained to find that halftone exposure can prevent unnecessary reflected light and stray light during the exposure when a sub-spacer is formed on the surface of a substrate including thin-film transistor elements using a negative photoresist. Thereby, an increase in the width of the bottom edge of the formed sub-spacer is prevented. As a result, the inventors have arrived at the solution to the above problem, completing the present invention.

That is, one aspect of the present invention may be a method for manufacturing a liquid crystal display device, including: a step (A-1) of applying a negative photoresist to a surface of a first substrate including a thin-film transistor element to form a first film; a step (A-2) of exposing the first film in an exposure pattern including a first exposure region and a second exposure region in which an exposure dose is lower than an exposure dose in the first exposure region; a step (A-3) of developing the first film to form a first spacer in the first exposure region and a second spacer with a height less than a height of the first spacer in the second exposure region; a step (B-1) of applying a negative photoresist to a surface of a second substrate including a black matrix to form a second film; a step (B-2) of exposing the second film in an exposure pattern including a third exposure region which overlaps the black matrix and a fourth exposure region which overlaps the black matrix and in which an exposure dose is not higher than an exposure dose in the third exposure region; a step (B-3) of developing the second film to form a third spacer in the third exposure region and a fourth spacer with a height not greater than a height of the third spacer in the fourth exposure region; and a step (C) of bonding the first substrate to the second substrate, whereby a top of the first spacer comes into contact with a top of the third spacer, and a top of the second spacer faces but does not come into contact with a top of the fourth spacer.

Another aspect of the present invention may be a liquid crystal display device, including: a first substrate including a thin-film transistor element; a second substrate including a black matrix; a liquid crystal layer disposed between the first substrate and the second substrate; a first spacer and a second spacer disposed on a liquid crystal layer side of the first substrate; and a third spacer and a fourth spacer disposed on a liquid crystal layer side of the second substrate and overlapping the black matrix, the first spacer being formed from a negative photoresist, the second spacer being formed from a negative photoresist and having a height less than a height of the first spacer, the third spacer being formed from a negative photoresist, the fourth spacer being formed from a negative photoresist and having a height not greater than a height of the third spacer, and a top of the first spacer being in contact with a top of the third spacer, and a top of the second spacer facing but not being in contact with a top of the fourth spacer, under no load.

The present invention can provide a method for manufacturing a liquid crystal display device in which a decrease in the aperture ratio is prevented while the load capacity is maintained, and a liquid crystal display device manufactured by this method.

### BRIEF DESCRIPTION OF THE DRAWINGS

FIG. 1A is a schematic cross-sectional view illustrating a method of forming spacers on a first substrate in a method for manufacturing a liquid crystal display device of an embodiment.

FIG. 1B is a schematic cross-sectional view illustrating the method of forming spacers on the first substrate in the method for manufacturing a liquid crystal display device of the embodiment.

FIG. 1C is a schematic cross-sectional view illustrating the method of forming spacers on the first substrate in the method for manufacturing a liquid crystal display device of the embodiment.

FIG. 2A is a schematic cross-sectional view illustrating a method of forming spacers on a second substrate in the method for manufacturing a liquid crystal display device of the embodiment.

FIG. 2B is a schematic cross-sectional view illustrating the method of forming spacers on the second substrate in the method for manufacturing a liquid crystal display device of the embodiment.

FIG. 2C is a schematic cross-sectional view illustrating the method of forming spacers on the second substrate in the method for manufacturing a liquid crystal display device of the embodiment.

FIG. 3 is a schematic cross-sectional view of a liquid crystal display device of the embodiment.

FIG. 4 is a schematic cross-sectional view of a conventional liquid crystal display device.

FIG. 5 is a schematic cross-sectional view of a region where the second spacer and the fourth spacer are disposed in FIG. 4.

FIG. 6 is a schematic cross-sectional view of a region where the second spacer and the fourth spacer are disposed in FIG. 3.

FIG. 7 is a schematic cross-sectional view in which the size of the fourth spacer shown in FIG. 5 is enlarged.

FIG. 8 illustrates the evaluation results of the relationship between the degree of an increase in the width of the bottom edge of a spacer and the exposure dose during the exposure.

FIG. 9 illustrates the evaluation results of the relationship among the degree of an increase in the width of the bottom edge of a spacer, the size of the spacer, and the types of the underlying layer for the spacer.

### DETAILED DESCRIPTION OF THE INVENTION

Hereinafter, the present invention is described in more detail based on an embodiment with reference to the drawings. The embodiment, however, is not intended to limit the scope of the present invention. The configurations of the embodiment may appropriately be combined or modified within the spirit of the present invention.

The expression “X to Y” as used herein means “not lower than X and not greater than Y”.

### Embodiment

A method for manufacturing a liquid crystal display device and a liquid crystal display device manufactured by this method of an embodiment are described below.

### <Formation of Spacer on First Substrate>

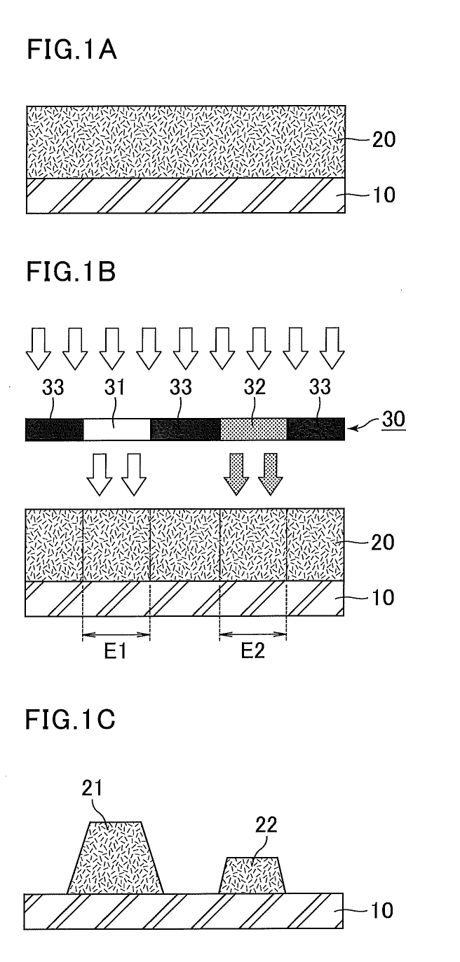

First, a method of forming spacers on a first substrate is described below with reference to FIGS. 1A, 1B, and 1C. FIGS. 1A, 1B, and 1C are schematic cross-sectional views each illustrating the method of forming spacers on the first substrate in the method for manufacturing a liquid crystal display device of the embodiment.

### (Application Step)

As shown in FIG. 1A, a negative photoresist is applied to the surface of a first substrate 10 to form a first film 20.

The first substrate 10 is a so-called thin-film transistor array substrate including thin-film transistor elements. The thin-film transistor array substrate may be one usually used in the field of liquid crystal display devices. A thin-film transistor array substrate having a configuration including members such as thin-film transistor elements, scanning lines, signal lines, pixel electrodes on the surface of a transparent substrate may be used, for example. The first substrate 10 includes materials such as a transparent material and a metal material. Examples of the transparent material in the first substrate 10 include glass that constitutes a transparent substrate, an insulating film (e.g., silicon nitride, silicon oxide), and a transparent conductive film (e.g., indium tin oxide). Examples of the metal material in the first substrate 10 include aluminum that constitutes scanning lines and signal lines.

The negative photoresist is a photosensitive resin in which the portion exposed to light becomes insoluble to the developer. Thus, an exposed portion of the negative photoresist remains after development and an unexposed portion thereof is removed during development. The negative photoresist may be one usually used in the field of liquid crystal display devices (for spacers).

The thickness of the first film 20 may be appropriately determined according to the desired heights of the below-described first spacer and the second spacer (e.g., set to equal to to twice the desired heights of the first spacer and the second spacer). The thickness may be 1 to 5 μm, for example.

### (Exposure Step)

As shown in FIG. 1B, the first film 20 is exposed in an exposure pattern including a first exposure region E1 and a second exposure region E2. In this step, so-called halftone exposure is performed in which the exposure dose in the second exposure region E2 is lower than the exposure dose in the first exposure region E1. The first exposure region E1 corresponds to the region where the below-described first spacer is to be formed, and the second exposure region E2 corresponds to the region where the below-described second spacer is to be formed. In the present embodiment, such halftone exposure is achieved by exposure through a halftone mask 30.

The halftone mask 30 includes a full transmissive part 31 corresponding to the first exposure region E1, a half transmissive part 32 corresponding to the second exposure region E2, and light shielding parts 33 corresponding to regions other than these regions. The half transmissive part 32 has a light transmittance lower than the light transmittance of the full transmissive part 31. The light transmittance of the half transmissive part 32 is 10% to 40%, for example, with the light transmittance of the full transmissive part 31 taken as 100%. When the halftone mask 30 is used, the exposure dose in the second exposure region E2 is 10% to 40% of the exposure dose in the first exposure region E1. The half transmissive part 32 can be formed to have a desired light transmittance which is controlled by vapor deposition of a metal thin film on the base (e.g., made of quartz) of the mask.

### (Development Step)

As shown in FIG. 1C, the first film 20 is developed to form a first spacer 21 and a second spacer 22 in the first exposure region E1 and the second exposure region E2, respectively. The first spacer 21 and the second spacer 22 can be formed at any position on the surface of the first substrate 10. For example, the first spacer 21 and the second spacer 22 may be formed to overlap metal lines such as scanning lines and signal lines.

The height of the second spacer 22 is less than the height of the first spacer 21. This is because the exposure dose in the second exposure region E2 for the formation of the second spacer 22 is lower than the exposure dose in the first exposure region E1 for the formation of the first spacer 21. The height of the first spacer 21 is 0.5 to 1.8 μm, for example. The height of the second spacer 22 is 0.5 to 1.6 μm, for example.

The cross-sectional shapes of the first spacer 21 and the second spacer 22 each may be a so-called tapered shape that tapers from the bottom on the first substrate 10 side toward the top facing the side opposite to the first substrate 10. In the case where the first spacer 21 and the second spacer 22 have tapered cross-sectional shapes, the gradient and other parameters thereof change according to the exposure dose during the exposure.

The three-dimensional shapes of the first spacer 21 and the second spacer 22 each may be a columnar shape or a wall shape (bank shape), for example.

The planar shapes of the first spacer 21 and the second spacer 22 each may be a polygonal shape, a circular shape, or an elliptical shape, for example.

### <Formation of Spacer on Second Substrate>

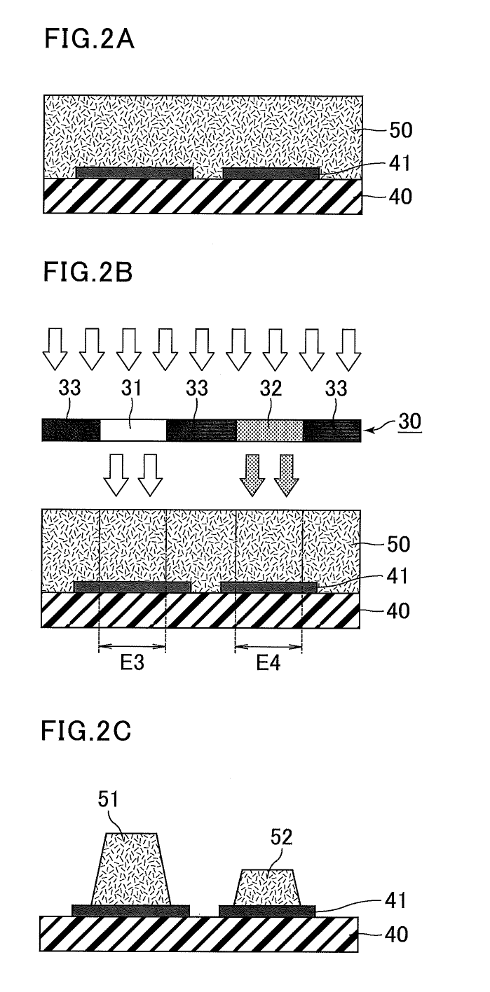

Then, a method of forming spacers on the second substrate is described below with reference to FIGS. 2A, 2B, and 2C. FIGS. 2A, 2B, and 2C are schematic cross-sectional views each illustrating the method of forming spacers on the second substrate in the method for manufacturing a liquid crystal display device of the embodiment.

### (Application Step)

As shown in FIG. 2A, a negative photoresist is applied to the surface of a second substrate 40 to form a second film 50. The second substrate 40 is a substrate including a black matrix 41. It may be a counter substrate for monochrome liquid crystal display or a color filter substrate, for example. The black matrix 41 may be one usually used in the field of liquid crystal display devices.

### (Exposure Step)

As shown in FIG. 2B, the second film 50 is exposed in an exposure pattern including a third exposure region E3 and a fourth exposure region E4 that overlap the black matrix 41. In this case, the exposure dose in the fourth exposure region E4 is not higher than the exposure dose in the third exposure region E3. The third exposure region E3 corresponds to the region where the below-described third spacer is to be formed, and the fourth exposure region E4 corresponds to the region where the below-described fourth spacer is to be formed.

The halftone mask 30 used in the exposure step may be the same as or different from the halftone mask 30 used for the formation of spacers (exposure step) on the first substrate 10. In the halftone mask 30, the full transmissive part 31 corresponds to the third exposure region E3, the half transmissive part 32 corresponds to the fourth exposure region E4, and the light shielding parts 33 correspond to regions other than these regions.

The light transmittance of the full transmissive part 31 and/or the light transmittance of the half transmissive part 32 of the halftone mask 30 may not be equal to those of the halftone mask 30 used for the formation of spacers (exposure step) on the first substrate 10. Alternatively, a photomask including the full transmissive parts corresponding to the third exposure region E3 and the fourth exposure region E4 and the light shielding parts corresponding to regions other than these regions may be used instead of the halftone mask 30.

### (Development Step)

As shown in FIG. 2C, the second film 50 is developed to form a third spacer 51 and a fourth spacer 52 in the third exposure region E3 and the fourth exposure region E4, respectively. As a result, the third spacer 51 and the fourth spacer 52 are formed to overlap the black matrix 41.

Although the height of the fourth spacer 52 is less than the height of the third spacer 51 in FIG. 2C, the fourth spacer 52 and the third spacer 51 may equal in height. That is, the height of the fourth spacer 52 is not greater than the height of the third spacer 51. For example, the fourth spacer 52 with a height less than the height of the third spacer 51 can be formed as shown in FIG. 2C by setting the exposure dose in the fourth exposure region E4 lower than the exposure dose in the third exposure region E3 using the halftone mask 30. Alternatively, the fourth spacer 52 equal in height to the third spacer 51 can be formed when the exposure dose in the fourth exposure region E4 is equal to the exposure dose in the third exposure region E3. The height of the third spacer 51 is 0.5 to 1.8 μm, for example. The height of the fourth spacer 52 is 0.5 to 1.6 μm, for example.

The cross-sectional shapes of the third spacer 51 and the fourth spacer 52 each may be a so-called tapered shape that tapers from the bottom on the second substrate 40 side toward the top facing the side opposite to the second substrate 40. In the case where the third spacer 51 and the fourth spacer 52 have tapered cross-sectional shapes, the gradient and other parameters thereof change according to the exposure dose during the exposure.

The three-dimensional shapes of the third spacer 51 and the fourth spacer 52 each may be a columnar shape or a wall shape (bank shape), for example.

The planar shapes of the third spacer 51 and the fourth spacer 52 each may be a polygonal shape, a circular shape, or an elliptical shape, for example.

### <Bonding of First Substrate to Second Substrate>

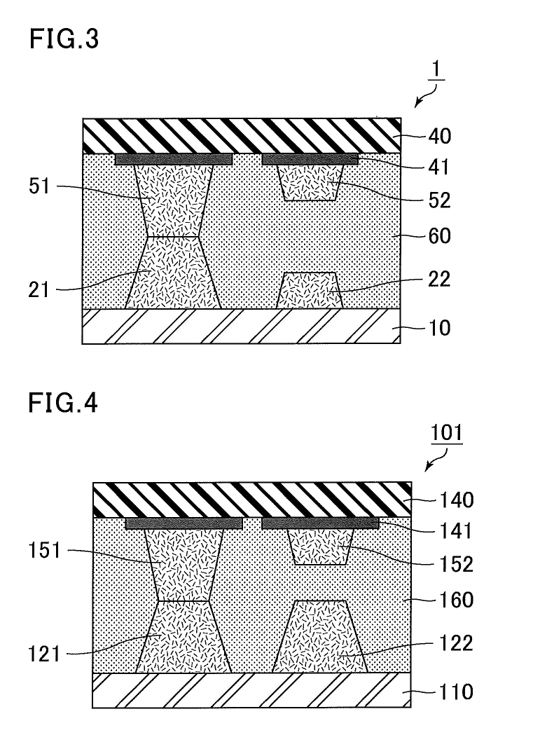

Then, the first substrate 10 is bonded to the second substrate 40, whereby the top of the first spacer 21 comes into contact with the top of the third spacer 51, and the top of the second spacer 22 faces but does not come into contact with the top of the fourth spacer 52. Thereby, a liquid crystal display device 1 as shown in FIG. 3 is manufactured. FIG. 3 is a schematic cross-sectional view of a liquid crystal display device of the embodiment.

The liquid crystal display device 1 includes the first substrate 10, the second substrate 40, a liquid crystal layer 60 disposed between the first substrate 10 and the second substrate 40, the first spacer 21 and the second spacer 22 disposed on the liquid crystal layer 60 side of the first substrate 10, and the third spacer 51 and the fourth spacer 52 disposed on the liquid crystal layer 60 side of the second substrate 40 and overlapping the black matrix 41.

The underlying layer for the third spacer 51 and the fourth spacer 52 is the black matrix 41. The underlying layer for the first spacer 21 and the second spacer 22 may be metal lines such as scanning lines and signal lines, for example. In the pixel region of the liquid crystal display device 1, the black matrix 41 of the second substrate 40 faces the metal lines such as scanning lines and signal lines of the first substrate 10 in some cases.

The liquid crystal layer 60 is formed by enclosing a liquid crystal material between the first substrate 10 and the second substrate 40 by one drop filling, injection, or other methods. The liquid crystal material may be a positive liquid crystal material having positive anisotropy of dielectric constant or a negative liquid crystal material having negative anisotropy of dielectric constant.

When the liquid crystal layer 60 is formed by one drop filling, the method may use the following process, for example. First, a sealing material is applied to the surface of one of the first substrate 10 (having the first spacer 21 and the second spacer 22 on the surface thereof) and the second substrate 40 (having the third spacer 51 and the fourth spacer 52 on the surface thereof), and a liquid crystal material is dropped on the surface of the other substrate. Then, the first substrate 10 and the second substrate 40 are bonded to each other with the sealing material, and the sealing material is cured. Thereby, the liquid crystal layer 60 is formed.

When the liquid crystal layer 60 is formed by injection, the method may use the following process, for example. First, a sealing material is applied to the surface of one of the first substrate 10 (having the first spacer 21 and the second spacer 22 on the surface thereof) and the second substrate 40 (having the third spacer 51 and the fourth spacer 52 on the surface thereof), the first substrate 10 and the second substrate 40 are bonded to each other with the sealing material, and the sealing material is cured. Then, the space between the first substrate 10 and the second substrate 40 is rendered vacuum and the liquid crystal material is injected into the space. Thereby, the liquid crystal layer 60 is formed.

The first spacer 21 and the third spacer 51 are in contact with each other at their tops to serve as so-called main spacers that maintain the space (thickness of the liquid crystal layer) between the first substrate 10 and the second substrate 40.

The top of the second spacer 22 faces but is not in contact with the top of the fourth spacer 52 when no load is applied to the liquid crystal display device 1, whereas they are in contact with each other at their tops to serve as so-called sub-spacers when the space between the first substrate 10 and the second substrate 40 (thickness of the liquid crystal layer 60) is reduced in the liquid crystal display device 1 under load.

When no load is applied to the liquid crystal display device 1, the first spacer 21 and the third spacer 51 (main spacers) being in contact with each other at their tops function effectively. Thus, these spacers are likely to follow the contraction of the liquid crystal layer 60 in a low temperature environment. The minimum required number of the first spacers 21 each having a minimum required size and the minimum required number of the third spacers 51 each having a minimum required size are disposed so that these spacers can follow the contraction of the liquid crystal layer 60. From the point of view, in the liquid crystal display device 1, the number of the first spacers 21 is preferably smaller than the number of the second spacers 22, and the number of the third spacers 51 is preferably smaller than the number of the fourth spacers 52. From the same point of view, the area of the top of the first spacer 21 is preferably smaller than the area of the top of the second spacer 22, and the area of the top of the third spacer 51 is preferably smaller than the area of the top of the fourth spacer 52.

On the other hand, when the space between the first substrate 10 and the second substrate 40 is reduced in the liquid crystal display device 1 under load, the combination of the first spacer 21 and the third spacer 51 (main spacers) and the combination of the second spacer 22 and the fourth spacer 52 (sub-spacers) can support these substrates together. Thereby, the load capacity increases. From the point of view, in the liquid crystal display device 1, the number of the second spacers 22 is preferably greater than the number of the first spacers 21, and the number of the fourth spacers 52 is preferably greater than the number of the third spacers 51. From the same point of view, the area of the top of the second spacer 22 is preferably greater than the area of the top of the first spacer 21, and the area of the top of the fourth spacer 52 is preferably greater than the area of the top of the third spacer 51.

In the liquid crystal display device 1, the number of the second spacers 22 is, for example, several times to several hundred times the number of the first spacers 21.

The area of the top of the second spacer 22 is, for example, a fraction to several times the area of the top of the first spacer 21.

The second spacer 22 is formed in the second exposure region E2 with a low exposure dose. Thus, unnecessary reflected light and stray light are prevented (prevented to the extent that the negative photoresist is not exposed) during the exposure even when the underlying layer is a transparent material, a metal material (e.g., scanning lines, signal lines), or other materials. As a result, an increase in the width of the bottom edge (increase in the width of the bottom) is prevented. For this reason, there is no need to increase the width of the black matrix 41 of the second substrate 40 to hide the second spacer 22 in a plan view. Thus, a decrease in the aperture ratio can be prevented. In addition, the width of the bottom edge of the second spacer 22 can be reduced to the same level as the width of the bottom edge of the fourth spacer 52, the underlying layer for the fourth spacer 52 being the black matrix 41, by lowering the exposure dose in the second exposure region E2.

The second spacer 22 is formed to have a height less than the height of the first spacer 21. Thus, a difference in height between the first spacer 21 and the second spacer 22 can be efficiently created. As a result, the distance between the top of the second spacer 22 and the top of the fourth spacer 52 (the sum of the height difference between the first spacer 21 and the second spacer 22 and the height difference between the third spacer 51 and the fourth spacer 52), which is one of the indices to adjust the load capacity of the liquid crystal display device 1, can be efficiently controlled.

In order to increase the distance between the top of the second spacer 22 and the top of the fourth spacer 52, the exposure dose in the second exposure region E2 for the formation of the second spacer 22 may be reduced (the light transmittance of the half transmissive part 32 of the halftone mask 30 is reduced) to form the second spacer 22 with a small height, for example. Thereby, an increase in the width of the bottom edge of the second spacer 22 is further prevented, and thus a decrease in the aperture ratio is further prevented.

When the exposure dose in the fourth exposure region E4 is equal to the exposure dose in the third exposure region E3, the fourth spacer 52 and the third spacer 51 are equal in height. In this case, the distance between the top of the second spacer 22 and the top of the fourth spacer 52 is controlled by adjusting the height of the second spacer 22. In order to increase the distance between the top of the second spacer 22 and the top of the fourth spacer 52, the height of the second spacer 22 may be reduced. Thereby, an increase in the width of the bottom edge of the second spacer 22 can be efficiently prevented. From the point of view, the exposure dose in the fourth exposure region E4 is preferably equal to the exposure dose in the third exposure region E3.

In order to reduce the distance between the top of the second spacer 22 and the top of the fourth spacer 52, the exposure dose in the fourth exposure region E4 for the formation of the fourth spacer 52 may be increased (the light transmittance of the half transmissive part 32 of the halftone mask 30 is increased) to form the fourth spacer 52 with a great height, for example. The underlying layer for the fourth spacer 52 is the black matrix 41. Thus, unnecessary reflected light and stray light are prevented during the exposure even when the exposure dose in the fourth exposure region E4 is increased. As a result, an increase in the width of the bottom edge can be prevented.

In order to increase the load capacity, the distance between the top of the second spacer 22 and the top of the fourth spacer 52 is preferably 0.4 to 0.6 μm. The height of the second spacer 22 is preferably less than the height of the first spacer 21 by 0.2 to 0.6 μm. Specifically, when the height of the third spacer 51 is not equal to the height of the fourth spacer 52, the height of the second spacer 22 is preferably less than the height of the first spacer 21 by 0.2 to 0.3 μm. When the third spacer 51 and the fourth spacer 52 are equal in height, the height of the second spacer 22 is preferably less than the height of the first spacer 21 by 0.4 to 0.6 μm.

The first spacer 21 is formed in the first exposure region E1 in which the exposure dose is higher than the exposure dose in the second exposure region E2. Thereby, the width of the bottom edge (the width of the bottom) of the first spacer 21 is larger than the width of the bottom edge (the width of the bottom) of the second spacer 22. However, since the minimum required number of the first spacers 21 each having a minimum required size is disposed so that these spacers can follow the contraction of the liquid crystal layer 60 in a low temperature environment, the first spacers 21 have a small influence on the aperture ratio compared to the second spacer 22. According to the present embodiment, an increase in the width of the bottom edge of the second spacer 22 that has a dominant influence on the aperture ratio is prevented. Thereby, a decrease in the aperture ratio is prevented even when the width of the bottom edge of the first spacer 21 is larger than the width of the bottom edge of the second spacer 22.

In order to increase the aperture ratio, the width of the bottom of the second spacer 22 is preferably less than the width of the bottom of the first spacer 21 and less than the width of the black matrix 41 serving as an underlying layer for the counter fourth spacer 52.

The underlying layer for the third spacer 51 and the fourth spacer 52 is the black matrix 41. Thus, unnecessary reflected light and stray light are prevented during the exposure. As a result, an increase in the width of the bottom edge (increase in the width of the bottom) is prevented.

In order to increase the aperture ratio, the width of the bottom of the fourth spacer 52 is preferably less than the width of the bottom of the third spacer 51.

Consequently, according to the present embodiment, a decrease in the aperture ratio is prevented even when the first spacer 21 and the second spacer 22 are concurrently formed using a negative photoresist at any position on the surface of the first substrate 10 including thin-film transistor elements.

In the present embodiment, the first spacer 21 and the second spacer 22 different in height are concurrently formed on the surface of the first substrate 10 by halftone exposure (halftone mask 30) using a negative photoresist. This is technically advantageous compared to halftone exposure using a positive photoresist. A halftone mask for positive photoresists is disadvantageous in terms of the formation accuracy of half transmissive parts compared to a halftone mask for negative photoresists. Also, in the present embodiment, the same material (negative photoresist) and the same production line (production apparatus) can be used for the formation of the first spacer 21 and the second spacer 22 on the first substrate 10 side and the formation of the third spacer 51 and the fourth spacer 52 on the second substrate 40 side. Thereby, the production efficiency increases.

The following describes the effectiveness in improving the aperture ratio obtained by the present embodiment while a conventional liquid crystal display device is exemplified.

FIG. 4 is a schematic cross-sectional view of a conventional liquid crystal display device. A liquid crystal display device 101 includes a first substrate 110 including thin-film transistor elements, a second substrate 140 including a black matrix, a liquid crystal layer 160 disposed between the first substrate 110 and the second substrate 140, a first spacer 121 and a second spacer 122 disposed on the liquid crystal layer 160 side of the first substrate 110, and a third spacer 151 and a fourth spacer 152 disposed on the liquid crystal layer 160 side of the second substrate 140 and overlapping the black matrix 141.

The first spacer 121 and the third spacer 151 are in contact with each other at their tops to serve as so-called main spacers that maintain the space (thickness of the liquid crystal layer 160) between the first substrate 110 and the second substrate 140.

The top of the second spacer 122 faces but is not in contact with the top of the fourth spacer 152 when no load is applied to the liquid crystal display device 101. In contrast, they are in contact with each other at their tops to serve as so-called sub-spacers when the space between the first substrate 110 and the second substrate 140 (thickness of the liquid crystal layer 160) is reduced in the liquid crystal display device 101 under load.

The first spacer 121 and the second spacer 122 are formed using a negative photoresist, but are different from the first spacer 21 and the second spacer 22 in that the first spacer 121 and the second spacer 122 are both formed in the regions with a high exposure dose (e.g., first exposure region E1). Thus, the width of the bottom edge of each spacer increases to the same level as the width of the bottom edge of the first spacer 21. The first spacer 121 and the second spacer 122 are equal in height.

The third spacer 151 and the fourth spacer 152 are formed in the same manner as for the third spacer 51 and the fourth spacer 52 in the above-described embodiment using a negative photoresist (using the halftone mask 30 during the exposure). The height of the fourth spacer 152 is less than the height of the third spacer 151.

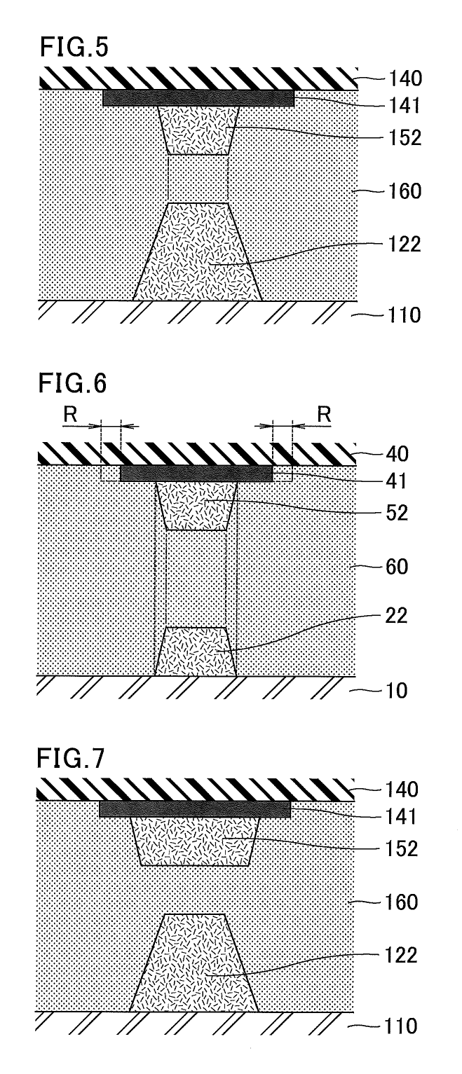

FIG. 5 is a schematic cross-sectional view of a region where the second spacer and the fourth spacer are disposed in FIG. 4. FIG. 6 is a schematic cross-sectional view of a region where the second spacer and the fourth spacer are disposed in FIG. 3.

As shown in FIG. 5, the area of the top of the second spacer 122 (the width of the top in FIG. 5) is equal to the area of the top of the fourth spacer 152 (the width of the top in FIG. 5). The load capacity of the liquid crystal display device 101 is largely determined by the contact area between the top of the second spacer 122 and the top of the fourth spacer 152. Thus, even if only one of the area of the top of the second spacer 122 and the area of the top of the fourth spacer 152 is increased, the load capacity does not increase. The following describes the case of spacers with the same top area as shown in FIG. 5. In a conventional liquid crystal display device, the width of the bottom edge of the second spacer 122 is larger than the width of the bottom edge of the fourth spacer 152. In order to hide such a wide bottom edge, there is a need to increase the width of the black matrix 141 while additionally considering the margin for production.

In contrast, according to the above-described embodiment, the width of the bottom edge of the second spacer 22 is reduced to the same level as the width of the bottom edge of the fourth spacer 52 as shown in FIG. 6. Thus, the width of the black matrix 41 can be made smaller than the conventional one (shown in FIG. 5) by the width of R x 2 (the width of the eliminated portions of the black matrix). As a result, the aperture ratio is higher than the conventional aperture ratio.

In a conventional liquid crystal display device, the black matrix 141 has a large width, and thus the formation of the large size fourth spacer 152 is conceived as shown in FIG. 7. FIG. 7 is a schematic cross-sectional view in which the size of the fourth spacer shown in FIG. 5 is enlarged. However, the fourth spacer 152 having a bottom with a large area also has a top with a large area. This only increases the area not in contact with the top of the counter second spacer 122. For this reason, the load capacity does not change.

### [Evaluation 1]

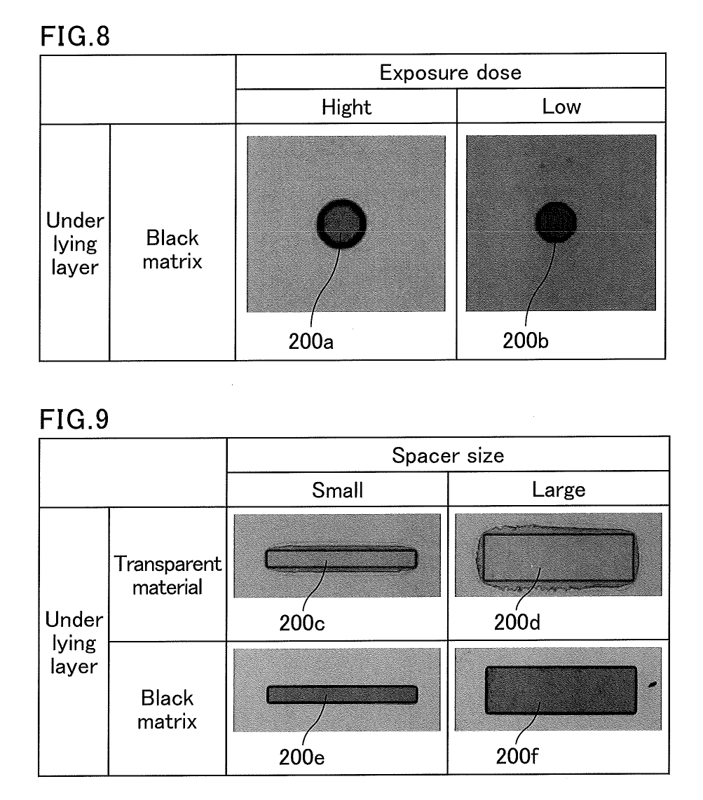

First, a negative photoresist was applied to the surface of a black matrix to form a film. Then, the film was halftone-exposed through a halftone mask and developed to form two types of spacers. One of the two types of spacers was formed in a first exposure region corresponding to the full transmissive part of the halftone mask and the other was formed in a second exposure region corresponding to the half transmissive part of the halftone mask. The light transmittance of the half transmissive part was 10% with the light transmittance of the full transmissive part taken as 100%. The exposure dose in the first exposure region was 50 to 300 mJ/cm², and the exposure dose in the second exposure region was 5 to 30 mJ/cm². For the thus formed two types of spacers, the change in the degree of an increase in the width of the bottom edge of each spacer relative to the exposure dose during the exposure was evaluated. FIG. 8 shows the results. FIG. 8 illustrates the evaluation results of the relationship between the degree of an increase in the width of the bottom edge of a spacer and the exposure dose during the exposure. FIG. 8 illustrates “the case of high exposure dose” as the first exposure region and “the case of low exposure dose” as the second exposure region.

As shown in FIG. 8, the width of the bottom edge of a spacer 200b formed by exposure at a low exposure dose was smaller than that of a spacer 200a formed by exposure at a high exposure dose. Specifically, the spacer 200a has a bottom 4.0 μm larger in size than the mask value of the photomask and a top equal in size to the mask value of the photomask. The spacer 200b has a bottom 1.3 μm larger in size than the mask value of the photomask and a top 1.0 μm smaller in size than the mask value of the photomask.

### [Evaluation 2]

First, a negative photoresist was applied to form a film. Then, the film was exposed through a photomask and developed to form spacers. Here, a total of four types of spacers were formed, which were different combinations of the types of the underlying layer (i.e., a transparent material or a black matrix) and the size of the spacer (i.e., a small size spacer or a large size spacer) (the size of exposure region). These four types of spacers were formed by exposure at the same exposure dose (50 to 300 mJ/cm²) as the exposure dose in the exposure through the full transmissive part (the case of high exposure dose) in Evaluation 1. For the thus formed four types of spacers, the change in the degree of an increase in the width of the bottom edge of each spacer relative to the size of the spacer and the types of the underlying layer for the spacer was evaluated. FIG. 9 shows the results. FIG. 9 illustrates the evaluation results of the relationship among the degree of an increase in the width of the bottom edge of a spacer, the size of the spacer, and the types of the underlying layer for the spacer.

As show in FIG. 9, the comparison between a small size spacer 200c and a large size spacer 200d, the underlying layer for both of the spacers being a transparent material, showed that an increase in the width of the bottom edge was observed in both of the spacers, the increase in the width of the bottom edge of the spacer 200d being more significant. This proved that in terms of the spacer size, the larger the size of a spacer, the wider the bottom edge when the underlying layer for the spacer was a transparent material.

On the other hand, as shown in FIG. 9, an increase in the width of the bottom edge was hardly observed in a small size spacer 200e and a large size spacer 200f, the underlying layer for both of the spacers being the black matrix. This proved that in terms of the types of the underlying layer for the spacer, an increase in the width of the bottom edge of a spacer was observed only in the case where the underlying layer is a transparent material.

Consequently, even if a sub-spacer large in size (specifically, area of the top) is formed in a region other than the black matrix serving as an underlying layer (e.g., a transparent material region serving as an underlying layer) to increase the load capacity of the liquid crystal display device, an increase in the width of the bottom edge of the sub-spacer is significant as shown in FIG. 9, and thus the aperture ratio decreases in a conventional liquid crystal display device. On the other hand, according to the present invention, a sub-spacer that has a dominant influence on the aperture ratio is formed by halftone exposure at a low exposure dose. Thus, an increase in the width of the bottom edge of the sub-spacer is prevented, and thereby a decrease in the aperture ratio is prevented. The present invention also enables the formation of a large size pattern such as an alignment mark in a substrate including thin-film transistor elements (thin-film transistor array substrate) using a negative photoresist while an increase in the width of the bottom edge is prevented.

### [Additional Remarks]

One aspect of the present invention may be a method for manufacturing a liquid crystal display device, including: a step (A-1) of applying a negative photoresist to a surface of a first substrate including a thin-film transistor element to form a first film; a step (A-2) of exposing the first film in an exposure pattern including a first exposure region and a second exposure region in which an exposure dose is lower than an exposure dose in the first exposure region; a step (A-3) of developing the first film to form a first spacer in the first exposure region and a second spacer with a height less than a height of the first spacer in the second exposure region; a step (B-1) of applying a negative photoresist to a surface of a second substrate including a black matrix to form a second film; a step (B-2) of exposing the second film in an exposure pattern including a third exposure region which overlaps the black matrix and a fourth exposure region which overlaps the black matrix and in which an exposure dose is not higher than an exposure dose in the third exposure region; a step (B-3) of developing the second film to form a third spacer in the third exposure region and a fourth spacer with a height not greater than a height of the third spacer in the fourth exposure region; and a step (C) of bonding the first substrate to the second substrate, whereby a top of the first spacer comes into contact with a top of the third spacer, and a top of the second spacer faces but does not come into contact with a top of the fourth spacer. In this aspect, the method for manufacturing a liquid crystal display device in which a decrease in the aperture ratio is prevented while the load capacity is maintained is achieved.

In this aspect, in the step (A-2), the exposure may be performed through a halftone mask. Thereby, the step (A-2) can be efficiently performed.

In this aspect, in the step (B-2), the exposure may be performed through a halftone mask. Thereby, the step (B-2) can be efficiently performed.

Another aspect of the present invention may be a liquid crystal display device, including: a first substrate including a thin-film transistor element; a second substrate including a black matrix; a liquid crystal layer disposed between the first substrate and the second substrate; a first spacer and a second spacer disposed on a liquid crystal layer side of the first substrate; and a third spacer and a fourth spacer disposed on a liquid crystal layer side of the second substrate and overlapping the black matrix, the first spacer being formed from a negative photoresist, the second spacer being formed from a negative photoresist and having a height less than a height of the first spacer, the third spacer being formed from a negative photoresist, the fourth spacer being formed from a negative photoresist and having a height not greater than a height of the third spacer, and a top of the first spacer being in contact with a top of the third spacer, and a top of the second spacer facing but not being in contact with a top of the fourth spacer, under no load. In this aspect, the liquid crystal display device in which a decrease in the aperture ratio is prevented while the load capacity is maintained is achieved.

What is claimed is:

1. A method for manufacturing a liquid crystal display device, comprising:
a step (A-1) of applying a negative photoresist to a surface of a first substrate including a thin-film transistor element to form a first film;
a step (A-2) of exposing the first film in an exposure pattern including a first exposure region and a second exposure region in which an exposure dose is lower than an exposure dose in the first exposure region;
a step (A-3) of developing the first film to form a first spacer in the first exposure region and a second spacer with a height less than a height of the first spacer in the second exposure region;
a step (B-1) of applying a negative photoresist to a surface of a second substrate including a black matrix to form a second film;
a step (B-2) of exposing the second film in an exposure pattern including a third exposure region which overlaps the black matrix and a fourth exposure region which overlaps the black matrix and in which an exposure dose is not higher than an exposure dose in the third exposure region;
a step (B-3) of developing the second film to form a third spacer in the third exposure region and a fourth spacer with a height not greater than a height of the third spacer in the fourth exposure region; and
a step (C) of bonding the first substrate to the second substrate, whereby a top of the first spacer comes into contact with a top of the third spacer, and a top of the second spacer faces but does not come into contact with a top of the fourth spacer.

2. The method for manufacturing a liquid crystal display device according to claim 1,
wherein in the step (A-2), the exposure is performed through a halftone mask.

3. The method for manufacturing a liquid crystal display device according to claim 1,
wherein in the step (B-2), the exposure is performed through a halftone mask.

4. A liquid crystal display device, comprising:
a first substrate including a thin-film transistor element;
a second substrate including a black matrix;
a liquid crystal layer disposed between the first substrate and the second substrate;
a first spacer and a second spacer disposed on a liquid crystal layer side of the first substrate; and
a third spacer and a fourth spacer disposed on a liquid crystal layer side of the second substrate and overlapping the black matrix,
the first spacer being formed from a negative photoresist,
the second spacer being formed from a negative photoresist and having a height less than a height of the first spacer,
the third spacer being formed from a negative photoresist,
the fourth spacer being formed from a negative photoresist and having a height not greater than a height of the third spacer, and
a top of the first spacer being in contact with a top of the third spacer, and a top of the second spacer facing but not being in contact with a top of the fourth spacer, under no load.
